(19) United States
(12) Patent Application Publication
(10) Pub. No.: US 2025/0314686 A1
(43) Pub. Date: Oct. 9, 2025

(54) Trailer Light Diagnostic Device

(71) Applicant: Arnold Scot Huggins, Spokane, WA (US)

(72) Inventor: Arnold Scot Huggins, Spokane, WA (US)

(21) Appl. No.: 18/973,273

(22) Filed: Dec. 9, 2024

Related U.S. Application Data
(60) Provisional application No. 63/574,504, filed on Apr. 4, 2024.

(51) Int. Cl. G01R 31/00; G01R 31/44

(52) U.S. Cl. CPC G01R 31/006; G01R 31/44

(57) ABSTRACT

A trailer light diagnostic device is provided. The device is comprised of a waterproof body with a wired or wireless adapter plug for flexible connectivity with trailer systems, using durable components such as corrosion-resistant coatings and secure Bluetooth or RF communication. A multi-functional display provides real-time visual feedback on circuit conditions of the trailer system, showing indicators for wiring faults and component functions like brake lights and turn signals, with dynamic color-coded icons for ease of use. Adjustable, impact-resistant mounts and fasteners, including magnetic and suction options, allow for secure attachment to various surfaces, while a reinforced hinge offers viewing angle flexibility.

### CROSS-REFERENCE TO RELATED APPLICATION

The present application claims priority to, and the benefit of, U.S. Provisional Application No. 63/574,504, which was filed on Apr. 4, 2024, and is incorporated herein by reference in its entirety.

### FIELD OF THE INVENTION

The present invention relates generally to the field of wiring malfunction identifiers. More specifically, the present invention relates to a trailer wiring diagnostic device featuring a waterproof, shock-resistant body and adaptable connectivity through wired or wireless adapter plugs for seamless integration with standard trailer connectors. The device is equipped with a real-time display for circuit feedback, color-coded indicators for easy identification, and flexible mounting options. Accordingly, the present disclosure makes specific reference thereto. Nonetheless, it is to be appreciated that aspects of the present invention are also equally applicable to other like applications, devices, and methods of manufacture.

### BACKGROUND

Traditional methods for checking the functionality of trailer lights typically involve the use of a multimeter or other forms of manual testing equipment. These approaches can be cumbersome and time-consuming, especially when there is only one person available to conduct the test. The complexity arises from the need to position oneself in two places at once: operating the vehicle's controls and simultaneously inspecting the lights at the back of the trailer. This inconvenience leads to repeated trips between the driver's seat and the rear of the trailer, making the testing process inefficient and exhausting. Moreover, roadside situations add another layer of urgency and difficulty. A trailer's lighting system is crucial for signaling braking, turning, and general visibility, all of which are critical for safe driving conditions. Any malfunction in these lights can lead to accidents or fines for failing to comply with safety regulations. Therefore, having a reliable and quick method for testing trailer lights is essential, especially in situations where breakdowns or last-minute checks are necessary. Additionally, traditional testing tools often require specialized knowledge to interpret readings, which can be an obstacle for drivers who are not mechanically inclined.

Therefore, there exists a long-felt need in the art for a trailer light diagnostic device that enables solo operators to test trailer lights without the need for additional assistance. There also exists a long-felt need in the art for a trailer light diagnostic device that provides immediate and clear feedback, thereby reducing the time required for testing. Moreover, there exists a long-felt need in the art for a trailer light diagnostic device that is simple to use in emergency situations, enhancing the safety and convenience of trailer maintenance.

The subject matter disclosed and claimed herein, in one embodiment thereof, comprises a trailer light diagnostic device. The device is comprised of a waterproof body with a wired or wireless adapter plug for flexible connectivity with trailer systems, using durable components such as corrosion-resistant coatings and secure Bluetooth or RF communication. A multi-functional display provides real-time visual feedback on the circuit conditions of the trailer system, showing indicators for wiring faults and component functions like brake lights and turn signals, with dynamic color-coded icons for ease of use. Adjustable, impact-resistant mounts and fasteners, including magnetic and suction options, allow for secure attachment to various surfaces, while a reinforced hinge offers viewing angle flexibility.

In this manner, the trailer light diagnostic device of the present invention accomplishes all the forgoing objectives and provides a compact and efficient solution that a single user can operate. It is designed to instantly identify the status of trailer lights, giving clear visual signals that indicate whether the lights are functioning correctly. The device's streamlined operation reduces the need for back-and-forth movement between the vehicle and the trailer, thus minimizing testing time and effort. By simplifying the process, especially in urgent or roadside conditions, this device significantly enhances the overall safety and practicality of trailer light inspections.

### SUMMARY

The following presents a simplified summary to provide a basic understanding of some aspects of the disclosed innovation. This summary is not an extensive overview, and it is not intended to identify key/critical elements or to delineate the scope thereof. Its sole purpose is to present some general concepts in a simplified form as a prelude to the more detailed description that is presented later.

The subject matter disclosed and claimed herein, in one embodiment thereof, comprises a trailer light diagnostic device. The device is comprised of a body constructed from waterproof, shock-resistant materials, such as high-density plastic or aircraft-grade aluminum, suitable for operation in various environments. The body may include reinforced edges or bumpers for impact protection. The body houses at least one wire connecting an adapter plug to a display screen, using multi-strand copper and insulated shielding to ensure signal integrity in high-vibration environments.

In some embodiments, the adapter plug can operate wirelessly, interfacing with trailer systems via Bluetooth or RF, and may include a self-contained power source. The adapter plug can also enter a low-power mode when inactive, reactivating upon connection. Designed for compatibility with multiple trailer types, the adapter plug supports 4-pin to 7-pin configurations and may include corrosion-resistant coatings for durability.

The display screen, which may be an LCD, LED, or OLED, shows diagnostic information clearly, even in bright or adverse conditions. It can adjust via a hinged mount for optimal viewing and is sealed against water ingress. The display provides a visual layout of trailer wiring circuits, with functions such as turn signals and brake lights, using color-coded, illuminated indicia for easy recognition. The screen dynamically updates to reflect circuit status in real-time and uses flashing patterns to indicate malfunctions.

The device includes a wirecode identifier on the body or display to match adapter plugs to the correct wiring configurations. Various fasteners enable secure mounting to vehicles or trailers, including options like magnets, clips, or suction cups. For more permanent attachment, threaded inserts are provided.

Accordingly, the trailer light diagnostic device of the present invention is particularly advantageous as it provides a compact and efficient solution that a single user can operate. It is designed to instantly identify the status of trailer lights, giving clear visual signals that indicate whether the lights are functioning correctly. The device's streamlined operation reduces the need for back-and-forth movement between the vehicle and the trailer, thus minimizing testing time and effort. By simplifying the process, especially in urgent or roadside conditions, this device significantly enhances the overall safety and practicality of trailer light inspections. In this manner, the trailer light diagnostic device overcomes the limitations of existing methods and devices used to check the functionality of trailer lights known in the art.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and are intended to include all such aspects and their equivalents. Other advantages and novel features will become apparent from the following detailed description when considered in conjunction with the drawings.

### BRIEF DESCRIPTION OF THE DRAWINGS

The description refers to provided drawings in which similar reference characters refer to similar parts throughout the different views, and in which:

FIG. 1 illustrates a front perspective view of one potential embodiment of a trailer light diagnostic device of the present invention in accordance with the disclosed architecture; and

FIG. 2 illustrates a rear perspective view of one potential embodiment of a trailer light diagnostic device of the present invention in accordance with the disclosed architecture.

### DETAILED DESCRIPTION

The innovation is now described with reference to the drawings, wherein like reference numerals are used to refer to like elements throughout. In the following description, for purposes of explanation, numerous specific details are set forth to provide a thorough understanding thereof. It may be evident, however, that the innovation can be practiced without these specific details. In other instances, well-known structures and devices are shown in block diagram form to facilitate a description thereof. Various embodiments are discussed hereinafter. It should be noted that the figures are described only to facilitate the description of the embodiments. They are not intended as an exhaustive description of the invention and do not limit the scope of the invention. Additionally, an illustrated embodiment need not have all the aspects or advantages shown. Thus, in other embodiments, any of the features described herein from different embodiments may be combined.

As noted above, there exists a long-felt need in the art for a trailer light diagnostic device that enables solo operators to test trailer lights without the need for additional assistance. There also exists a long-felt need in the art for a trailer light diagnostic device that provides immediate and clear feedback, thereby reducing the time required for testing. Moreover, there exists a long-felt need in the art for a trailer light diagnostic device that is simple to use in emergency situations, enhancing the safety and convenience of trailer maintenance.

The present invention, in one exemplary embodiment, is comprised of a trailer light diagnostic device. The device comprises a body made from waterproof, shock-resistant materials like high-density plastic or aircraft-grade aluminum, enabling reliable use in diverse environments. Reinforced edges or bumpers may provide additional impact protection. Within the body, at least one wire connects an adapter plug to a display screen, utilizing multi-strand copper and insulated shielding to maintain signal integrity under high-vibration conditions.

In certain configurations, the adapter plug operates wirelessly, interfacing with trailer systems through Bluetooth or RF, with an optional self-contained power source. When inactive, the adapter plug can enter low-power mode and reactivate upon connection. The plug supports 4-pin to 7-pin configurations for broad compatibility and may feature corrosion-resistant coatings.

The display screen, available as an LCD, LED, or OLED, delivers clear diagnostic information even in bright or adverse weather. It is adjustable via a hinged mount for optimal visibility and is water sealed. The display provides a visual layout of trailer wiring circuits, showing functions such as turn signals and brake lights, with color-coded, illuminated indicators for easy identification. It dynamically updates to reflect real-time circuit status and uses flashing patterns to signal malfunctions.

The device includes a wirecode identifier to match adapter plugs to appropriate wiring configurations. Various fasteners support secure mounting to vehicles or trailers, including magnets, clips, or suction cups, with threaded inserts available for permanent attachment.

The trailer light diagnostic device offers a compact, efficient solution operable by a single user. It provides immediate, clear visual feedback on trailer light functionality, minimizing movement between the vehicle and trailer and reducing testing time. By simplifying the inspection process, particularly in urgent situations, this device enhances safety and usability over existing methods for trailer light testing.

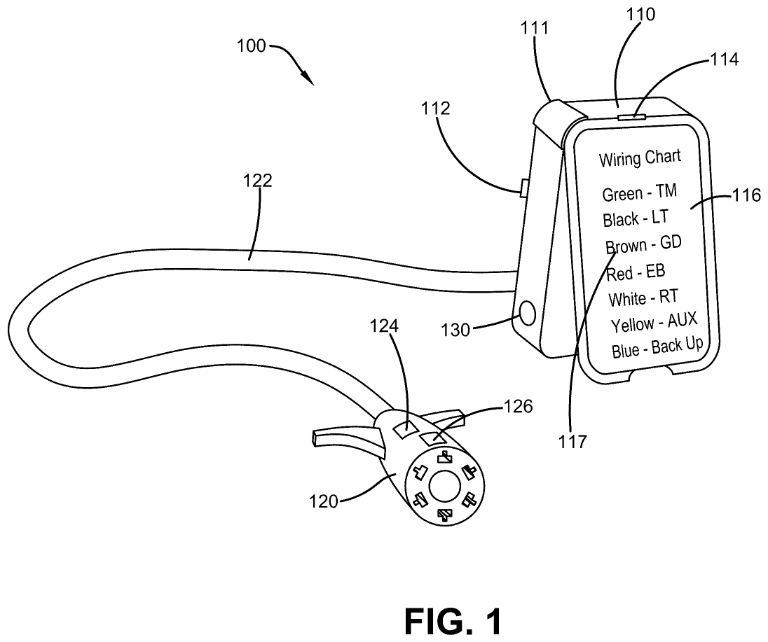

Referring initially to the drawings, FIG. 1 illustrates a front perspective view of one potential embodiment of a trailer light diagnostic device 100 of the present invention in accordance with the disclosed architecture. The device 100 is comprised of a body 110, which is preferably made of a waterproof, shock-resistant material to ensure reliable operation in a variety of environments, including heavy rain, snow, or dust. In one embodiment, this material may be a high-density waterproof plastic, such as polycarbonate or ABS plastic, engineered to resist impact and deformation, making the device suitable for outdoor use near trailers and towing vehicles. Additionally, the body 110 may feature reinforced edges or protective bumpers 111 to further safeguard internal components from accidental drops or collisions. Other materials, such as aircraft-grade aluminum with an anodized, waterproof coating, may also be used to provide superior strength while minimizing weight.

The body 110 is comprised of at least one wire 122, which is configured to establish a reliable wired communication link between at least one adapter plug 120 and at least one display screen 116 integrated into the body 110. The wire 122 may be constructed with multi-strand copper conductors for flexibility and minimal signal loss and comprised of an insulating jacketed wire to reduce electromagnetic interference (EMI) that can be present in environments with heavy vehicle operation. This shielding construction ensures consistent signal integrity, even in high-vibration settings, such as when the device 100 is used alongside trailers in transit or stationary testing on uneven ground.

In certain embodiments, the device 100 the adapter plug 120 may be wireless, which allows the plug 120 to interface with trailer wiring systems without a physical connection to the body 110 and/or display 116. The wireless adapter plug 120 communicates with the display 116 via a secure wireless protocol, such as Bluetooth Low Energy (BLE) or a dedicated RF (radio frequency) channel, ensuring reliable data transmission across short distances.

The wireless adapter plug 120 may be equipped with a self-contained power source 124, such as a rechargeable battery, or draw minimal power directly from the trailer's circuitry, allowing it to maintain continuous operation during testing. For energy efficiency, the wireless adapter plug 120 may enter a low-power standby mode when not in active use, automatically reactivating when a connection to the device 100 is established.

The adapter plug 120 is designed to interface seamlessly with standard trailer connectors, making the device compatible with a wide range of towing setups. Examples of adapter plug 120 configurations include, but are not limited to, 4-pin, 5-pin, 6-pin, and 7-pin connectors, which cover a spectrum of trailer wiring needs, from simple light functions to more complex setups involving electric brakes and auxiliary power. To enhance the durability and reliability of the adapter plug 120, the plug 120 may be constructed with a corrosion-resistant coating 126, such as nickel plating or weatherproof rubberized sheathing, to protect against rust and moisture ingress, especially during long-term outdoor exposure.

The display screen 116 is preferably any type of electronic display screen, such as an LCD, LED, or OLED display, capable of presenting diagnostic information with clarity, even under direct sunlight or in inclement weather. In one embodiment, the display screen 116 can be raised or lowered relative to the body 110 via at least one hinge 114, allowing the user to adjust the viewing angle for optimal visibility. The hinge 114 may be constructed of stainless steel or a high-durability polymer, with a locking mechanism to maintain a stable position in windy conditions and may also include a sealing system to prevent water ingress at the pivot point.

The display screen 116 is specifically configured to present a visual representation of a trailer's wiring circuits, including functions such as but not limited to “left turn signal,” “right turn signal,” “brake lights,” “reverse lights,” “tail lights,” and auxiliary power lines. These circuits may be depicted using indicia 117 such as but not limited to a combination of symbolic icons and descriptive labels to make the diagnostic process straightforward, even for users unfamiliar with trailer wiring schematics. The screen 116 is capable of dynamically updating in real-time as the device detects electrical signals or tests for continuity, providing instant feedback on the status of each circuit.

To make circuit identification intuitive, the indicia 117 may be color-coded in one embodiment. The color-coded indicia 117 may be comprised of bright, high-contrast LED segments, electroluminescent displays, or digital overlays that are easy to differentiate. For nighttime use or poor lighting conditions, the indicia 117 can be backlit or illuminated by the display 116.

When a circuit malfunction is detected—such as a broken wire, a short circuit, or an inconsistent signal—the indicia 117 may flash, pulse, or change color to draw immediate attention. Flashing patterns may be configured based on the nature of the malfunction: a slow, steady blink for non-critical issues, and rapid, high-intensity strobing for urgent faults.

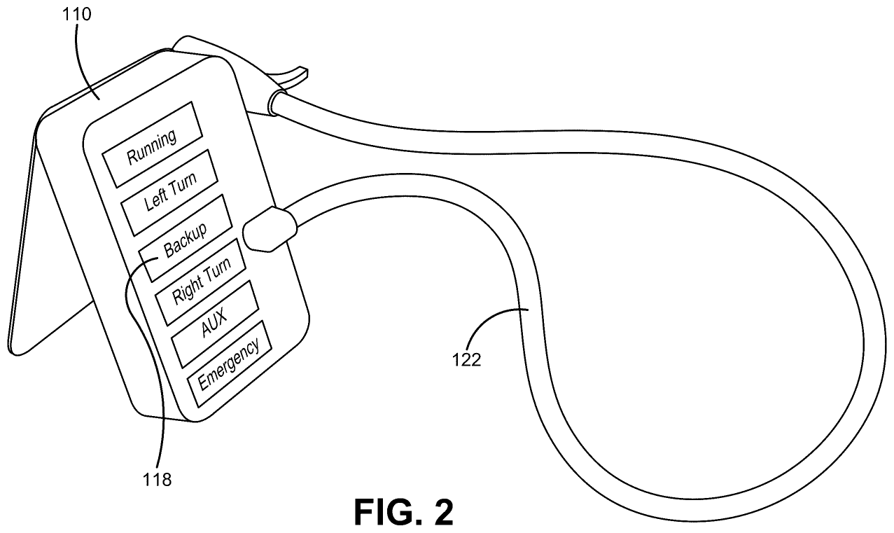

The body 110 also includes at least one wirecode 118, serving as a visual or digital identifier that matches the adapter plug 120 to the correct wiring configuration. This wirecode 118 may be etched, printed, or displayed on the body 110 (as seen in FIG. 2) or electronically on the screen 116, simplifying the process of verifying that the correct connection is being used for the specific trailer setup.

The body 110 may be equipped with at least one fastener 112, providing multiple options for securely attaching the device 100 to various surfaces, such as the side of a towing vehicle or the trailer frame itself. The fastener 112 could be a hook, a set of neodymium magnets strong enough to hold the device securely on metal surfaces, or adjustable clips that can clamp onto non-metallic structures. In some embodiments, the fastener 112 is comprised of a suction cup mechanism with a quick-release feature, offering secure yet easily removable mounting on smooth, non-porous surfaces. For more permanent installations, the device 100 may incorporate a fastener 112 in the form of a threaded insert compatible with standard bolts, allowing the device 100 to be firmly attached while ensuring a rust-resistant finish for extended outdoor use.

The device 100 may be turned on/off via at least one power button 130.

Certain terms are used throughout the following description and claims to refer to particular features or components. As one skilled in the art will appreciate, different persons may refer to the same feature or component by different names. This document does not intend to distinguish between components or features that differ in name but not structure or function. As used herein “trailer light diagnostic device” and “device” are interchangeable and refer to the trailer light diagnostic device 100 of the present invention.

Notwithstanding the forgoing, the trailer light diagnostic device 100 of the present invention and its various components can be of any suitable size and configuration as is known in the art without affecting the overall concept of the invention, provided that they accomplish the above-stated objectives. One of ordinary skill in the art will appreciate that the size, configuration, and material of the trailer light diagnostic device 100 as shown in the FIGS. are for illustrative purposes only, and that many other sizes and shapes of the trailer light diagnostic device 100 are well within the scope of the present disclosure. Although the dimensions of the trailer light diagnostic device 100 are important design parameters for user convenience, the trailer light diagnostic device 100 may be of any size, shape, and/or configuration that ensures optimal performance during use and/or that suits the user's needs and/or preferences.

Various modifications and additions can be made to the exemplary embodiments discussed without departing from the scope of the present invention. While the embodiments described above refer to particular features, the scope of this invention also includes embodiments having different combinations of features and embodiments that do not include all the described features. Accordingly, the scope of the present invention is intended to embrace all such alternatives, modifications, and variations as fall within the scope of the claims, together with all equivalents thereof.

What has been described above includes examples of the claimed subject matter. It is, of course, not possible to describe every conceivable combination of components or methodologies for purposes of describing the claimed subject matter, but one of ordinary skill in the art may recognize that many further combinations and permutations of the claimed subject matter are possible. Accordingly, the claimed subject matter is intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A trailer light diagnostic device comprising:
a body comprised of a waterproof material;
an adapter plug;
a display screen; and
a wire establishing a wired communication between the adapter plug and the display screen.

2. The trailer light diagnostic device of claim 1, wherein the body is comprised of a reinforced edge.

3. The trailer light diagnostic device of claim 1, wherein the body is comprised of a bumper.

4. The trailer light diagnostic device of claim 1, wherein the display screen attaches to the body via a hinge.

5. The trailer light diagnostic device of claim 1, wherein the body is comprised of a wirecode.

6. The trailer light diagnostic device of claim 1, wherein the display screen is configured to present a visual indicia representing a left turn signal, a right turn signal, a brake light, a reverse light, a tail light, or an auxiliary power line.

7. The trailer light diagnostic device of claim 1, wherein the adapter plug is comprised of a 4-pin adapter plug, a 5-pin adapter plug, a 6-pin adapter plug, or a 7-pin adapter plug.

8. The trailer light diagnostic device of claim 1, wherein the body is comprised of a fastener.

9. A trailer light diagnostic device comprising:
a body comprised of a waterproof material;
a display screen;
a wireless adapter plug in wireless communication with the display screen; and
a wire establishing a wired communication between the adapter plug and the display screen.

10. The trailer light diagnostic device of claim 9, wherein the display screen is configured to present a visual indicia representing a left turn signal, a right turn signal, a brake light, a reverse light, a tail light, or an auxiliary power line.

11. The trailer light diagnostic device of claim 10, wherein the visual indicia is comprised of a color-coded indicia.

12. The trailer light diagnostic device of claim 9, wherein the body is comprised of a magnet.

13. The trailer light diagnostic device of claim 9, wherein the body is comprised of a suction cup.

14. The trailer light diagnostic device of claim 9 further comprised of a power button.

15. The trailer light diagnostic device of claim 9 further comprised of a wirecode.

16. The trailer light diagnostic device of claim 15, wherein the wirecode is positioned on the body.

17. The trailer light diagnostic device of claim 15, wherein the wirecode is displayed on the display screen.

18. The trailer light diagnostic device of claim 15, wherein the wireless adapter plug is comprised of a rechargeable battery.

19. A trailer light diagnostic device comprising:
a body comprised of a waterproof material;
an adapter plug;
a display screen in communication with the adapter plug, the display screen operable to show a real-time diagnostic of a trailer circuit via an indicia; and
a wire establishing a wired communication between the adapter plug and the display screen.

20. The trailer light diagnostic device of claim 19, wherein the indicia flashes, pulses, or changes color to indicate a trailer circuit malfunction.
